(19) United States
(12) Patent Application Publication
(10) Pub. No.: US 2025/0378246 A1
(43) Pub. Date: Dec. 11, 2025

(54) AUTOMATED ON-CHIP INSTRUMENTATION FOR USE WITH FIELD-PROGRAMMABLE GATE ARRAYS

(71) Applicant: Microsemi SoC Corp., Chandler, AZ (US)

(72) Inventors: Manuel Alejandro Saldana De Fuentes, Toronto (CA); Jennifer Lan-Hwa Mah, Calgary (CA)

(73) Assignee: Microsemi SoC Corp., Chandler, AZ (US)

(21) Appl. No.: 18/789,867

(22) Filed: Jul. 31, 2024

Related U.S. Application Data
(60) Provisional application No. 63/657,254, filed on Jun. 7, 2024.

(51) Int. Cl. G06F 30/327; G06F 11/32

(52) U.S. Cl. CPC G06F 30/327; G06F 11/322

(57) ABSTRACT

A method for providing on-chip instrumentation comprises receiving a source code which specifies a design to be programmed into a field programmable gate array (FPGA); generating a high-level instrumentation specification derived from the source code and which indicates levels of components in the FPGA to instrument; generating a low-level instrumentation specification derived from the high-level instrumentation specification and which identifies specific components in the FPGA to instrument; receiving a dumpfile that includes data regarding the specific ports, the specific signals, and the specific operating parameters derived from data received from the FPGA; generating a waveform update file that includes data from the FPGA regarding the specific ports, the specific signals, and the specific operating parameters, the data generated in a format for viewing in a waveform viewer; and generating triggering data to determine a plurality of times at which the specific signals are sampled.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/657,254; titled “AUTOMATED ON-CHIP INSTRUMENTATION”; and filed Jun. 7, 2024. The Provisional application is hereby incorporated by reference, in its entirety, into the current patent application.

### FIELD OF THE INVENTION

Examples of the current technology relate to high-level, automated instrumentation and monitoring processes for hardware modules implemented on field-programmable gate arrays (FPGAs) using on-chip analyzers.

### BACKGROUND OF THE INVENTION

A field-programmable gate array (FPGA) includes a plurality of configurable logic blocks (CLBs), a plurality of higher function blocks, one or more memory blocks, one or more input/output (I/O) components, and an interconnect architecture that are integrated in a single package. The listed components within the FPGA are programmed or configured with a design that performs a variety of high-level functions or applications across numerous industries. The design is created by a user, such as an electronics hardware designer or engineer, a software programmer, or the like, who describes the design in more abstract, generalized terms in a high-level programming language such as C++. The C++ code is converted by software into a hardware description language (HDL) code that identifies specific hardware components and is used to program the FPGA. Often, the user would like to evaluate the performance of the design, troubleshoot the design, or both as it is operating on the FPGA. The evaluation, troubleshooting, or both is facilitated by instrumenting the FPGA, which includes configuring circuitry in the FPGA, in addition to the circuitry that is configured for the design, to provide observability or monitoring of ports, signals, and memory and I/O components within the design. In various examples, the observed or monitored ports, signals and memory and I/O components would not otherwise have normally been output by the FPGA as part of the design. Instrumenting the FPGA involves utilizing an instrumentor software program in which the user identifies, or lists, each specific port, signal, and memory and I/O component that is desired to be observed. Setting up the instrumentor can be a time-consuming and deliberate process. And, if the design needs to be changed to correct performance or operational issues, the user changes the C++ code which may result in different hardware components along with different ports, signals, and memory components and I/O being utilized. If any of these entities change, then the user has to set up the instrumentor again-leading to longer development time for the design.

The background discussion is intended to provide information related to the present technology which is not necessarily prior art.

### SUMMARY OF THE INVENTION

Various examples of the current technology address one or more of the above-mentioned problems and present a method for providing on-chip instrumentation for use with a field programmable gate array (FPGA) in which various ports, signals, and memory and input/output (I/O) components from a design may be automatically identified to be input into an instrumentor without explicit setup by a user. The method broadly comprises receiving a source code which specifies a design to be programmed into the FPGA and includes a plurality of statements describing a function of the design, one or more flows of data, or both; generating a high-level instrumentation specification derived from the source code and which includes one or more statements that indicate a level of ports, a level of signals, and a level of operating parameters for memory and I/O components in the FPGA to instrument; generating a low-level instrumentation specification derived from the high-level instrumentation specification and which includes one or more statements that identify a plurality of specific ports, a plurality of specific signals, and a plurality of specific operating parameters for specific memory and I/O components in the FPGA to instrument; receiving a dumpfile that includes data regarding the specific ports, the specific signals, and the specific operating parameters derived from data received from the FPGA; generating a waveform update file derived from the dumpfile that includes data from the FPGA regarding the specific ports, the specific signals, and the specific operating parameters, the data generated in a format for viewing in a waveform viewer; and generating triggering data to determine a plurality of times at which the specific signals are sampled.

Another example of the current technology provides a method for providing on-chip instrumentation for a field programmable gate array (FPGA), with the method broadly comprising receiving a source code from a user which specifies a design to be programmed into the FPGA and includes a plurality of statements describing a function of the design, one or more flows of data, or both, and one or more statements that indicate a level of ports, a level of signals, and a level of operating parameters for memory and input/output (I/O) components in the FPGA to instrument; generating a low-level instrumentation specification derived from the source code and which includes one or more statements that identify a plurality of specific ports, a plurality of specific signals, and a plurality of specific operating parameters for specific memory and I/O components in the FPGA to instrument; receiving a dumpfile that includes data regarding the specific ports, the specific signals, and the specific operating parameters derived from data received from the FPGA; generating a waveform update file derived from the dumpfile that includes data from the FPGA regarding the specific ports, the specific signals, and the specific operating parameters, the data generated in a format for viewing in a waveform viewer; and generating triggering data to determine a plurality of times at which the specific signals are sampled.

Yet another example of the current technology provides a plurality of software modules operating in combination for providing on-chip instrumentation for a field programmable gate array (FPGA), with the software modules broadly comprising a high-level synthesis tool, a high-level instrumentor, a triggering unit, and a waveform viewer updater. The high-level synthesis tool receives a source code which specifies a design to be programmed into the FPGA and includes a plurality of statements describing a function of the design, one or more flows of data, or both, generates a high-level instrumentation specification derived from the source code which includes one or more statements that indicate a level of ports, a level of signals, and a level of operating parameters for memory and input/output (I/O) components in the FPGA to instrument, and generates a design hardware description language (HDL) code that describes the design. The high-level instrumentor receives the high-level instrumentation specification and generates a low-level instrumentation specification derived from the high-level instrumentation specification and which includes one or more statements that identify a plurality of specific ports, a plurality of specific signals, and a plurality of specific operating parameters for specific memory and I/O components in the FPGA to instrument. The triggering unit receives the high-level instrumentation specification and generates triggering data to determine a plurality of times at which the specific signals are sampled. The waveform viewer updater receives a dumpfile that includes data regarding the specific ports, the specific signals, and the specific operating parameters derived from data received from the FPGA, and generates a waveform update file derived from the dumpfile that includes data from the FPGA regarding the specific ports, the specific signals, and the specific operating parameters, the data generated in a format for viewing in a waveform viewer.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic flow diagram of a method for providing on-chip instrumentation for use with a field programmable gate array (FPGA) according to various examples;

FIG. 2 is a schematic block diagram of a computing device utilized to perform at least a portion of the operation(s) of the method(s) of the examples discussed herein;

FIG. 3 is a listing of high-level instrumentation statements in .json code;

FIG. 4 is a listing of signals in a plurality of log level specification options for a component named axi stream; and

FIG. 5 is a schematic flow diagram of a method for providing on-chip instrumentation for use with an FPGA according to various examples.

The drawing figures do not limit the current technology to the specific examples disclosed and described herein. The drawings are not necessarily to scale, emphasis instead being placed upon clearly illustrating the principles of the technology.

### DETAILED DESCRIPTION OF THE INVENTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

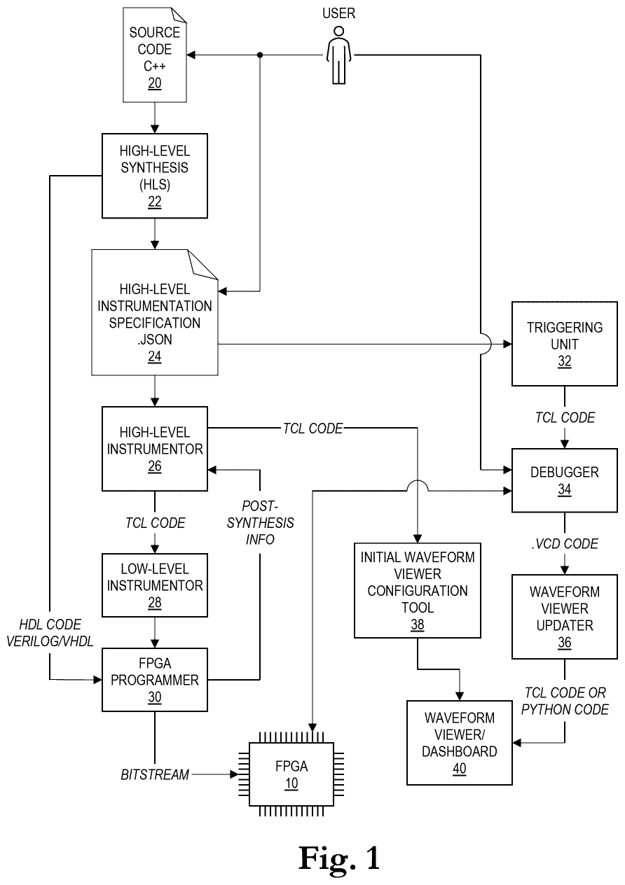

Referring to FIG. 1, a diagram illustrating a flow of a method for providing on-chip instrumentation for use with a field programmable gate array (FPGA) 10 is shown. The method is utilized by a user, who may be an electronics hardware designer or engineer, a software programmer, or the like, and/or a program running on a computing device, who/which has a design to be programmed into the FPGA 10 and would like to evaluate the performance of the design, troubleshoot the design, or both as it is operating on the FPGA 10. The design may perform a variety of high-level functions, processes, or applications that are utilized in wearable electronic devices, mobile electronic devices, consumer electronic devices, appliances, automobiles, industrial equipment, or the like. The evaluation, troubleshooting, or both is facilitated by instrumenting the FPGA 10, which includes configuring circuitry in the FPGA 10, in addition to the circuitry that is configured for the design, to provide observability or monitoring of ports, signals, and memory and input/output (I/O) components within the design. In various examples, the observed or monitored ports, signals and memory and I/O components would not otherwise have normally been output by the FPGA 10 as part of the design.

The FPGA 10 includes a plurality of configurable logic blocks (CLBs), a plurality of higher function blocks, one or more memory blocks, one or more input/output (I/O) components, and an interconnect architecture that are integrated in a single package. Each CLB includes gates, cells, or both which can perform various functions. The CLBs are typically configured to perform fundamental or low level arithmetic or logic operations in which some of the gates or cells may not be utilized. Multiple CLBs may be configured in combination to build one or more operational components. The higher function blocks include components such as multipliers, digital signal processing (DSP) blocks, general processor cores, transceiver circuitry, memory controllers, and so forth which are already constructed. The memory blocks store data that is input to, or output from, the CLBs and higher function blocks. The I/O components transfer data in and out of the design or the FPGA 10. The interconnect architecture provides pathways for data to be passed between the CLBs, the higher function blocks, and the memory blocks. When the FPGA 10 is programmed or configured, the CLBs, the higher function blocks, the memory blocks, the I/O components, and the interconnect pathways are selected and enabled as necessary to perform the functions and operations of the design.

In general, the FPGA 10 may be programmed before it is installed in a device or piece of equipment. Alternatively, the FPGA 10 may be programmed in-situ, or after it is installed in a device or piece of equipment. With examples of the current technology, the FPGA 10 may be programmed in a development environment, such as on a printed circuit board that can provide electronic communication with the components shown in FIG. 1 and described below.

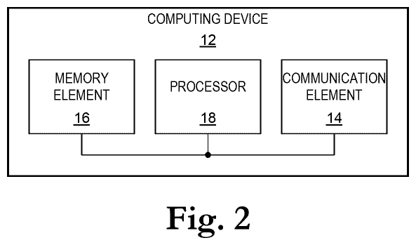

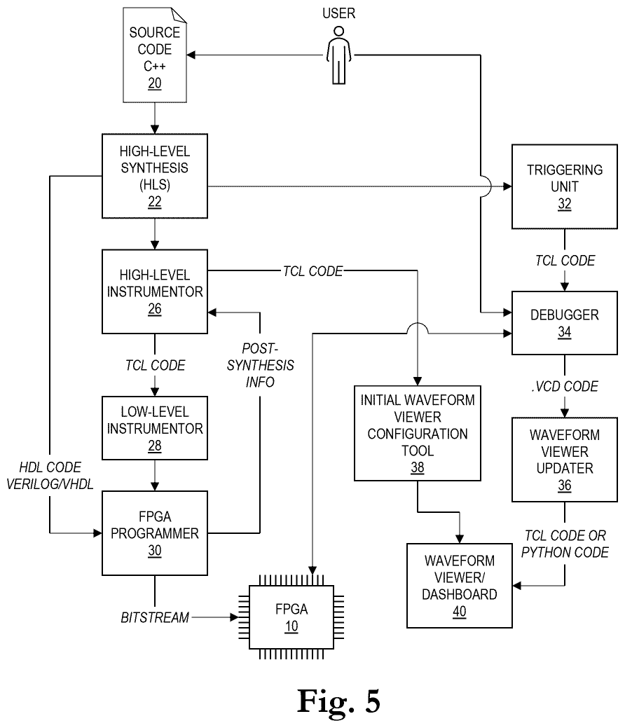

Various aspects of the methods disclosed herein are performed by a computing device 12 as shown in FIG. 2. For example, the components illustrated in FIGS. 1 and 5 may be stored, executed, processed, received by or otherwise manipulated by or on the computing device 12. In various examples, the illustrated components are in communication with the FPGA 10. The computing device 12 may be exemplified by workstation computers, desktop computers, laptop computers, palmtop computers, notebook computers, tablets or tablet computers, or the like. The computing device 12 comprises a communication element 14, a memory element 16, and a processor 18.

The communication element 14 generally allows the computing device 12 to communicate with the FPGA 10 and other computing devices, external systems, computing networks, telecommunication networks, the Internet, and the like. The communication element 14 may include signal and/or data transmitting and receiving circuits, such as antennas, amplifiers, filters, mixers, oscillators, digital signal processors (DSPs), and the like. The communication element 14 may establish communication wirelessly by utilizing radio frequency (RF) signals and/or data that comply with communication standards such as cellular 2G, 3G, 4G, Voice over Internet Protocol (VOIP), LTE, Voice over LTE (VOLTE), or 5G, Institute of Electrical and Electronics Engineers (IEEE) 802.11 standard such as WiFi, IEEE 802.16 standard such as WiMAX, Bluetooth™, or combinations thereof. In addition, the communication element 14 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 14 may establish communication through connectors or couplers that receive metal conductor wires or cables which are compatible with networking technologies such as ethernet. In various examples, the communication element 14 may also couple with optical fiber cables. The communication element 14 may be in electronic communication with the memory element 16 and the processor 18.

The memory element 16 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, hard disks, optical disks, flash memory, thumb drives, universal serial bus (USB) drives, solid state memory, or the like, or combinations thereof. In various examples, the memory element 16 may be embedded in, or packaged in the same package as, the processor 18. The memory element 16 may include, constitute, or embody, a non-transitory “computer-readable medium”. The memory element 16 may store the instructions, code, code statements, code segments, software, firmware, programs, applications, apps, services, daemons, or the like that are executed by the processor 18, for example those illustrated in FIGS. 1 and 5 other than the FPGA 10. The memory element 16 is in electronic communication with the processor 18 and may also store data that is received by the processor 18 or the device in which the processor 18 is implemented. The processor 18 may further store data or intermediate results generated during processing, calculations, and/or computations as well as data or final results after processing, calculations, and/or computations. In addition, the memory element 16 may store settings, text data, documents from word processing software, spreadsheet software and other software applications, sampled audio sound files, photograph or other image data, movie data, databases, and the like.

The processor 18 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The processor 18 may include or comprise one or more digital processing unit(s). The processor 18 may generally execute, process, or run instructions, code, code segments, code statements, software, firmware, programs, applications, apps, processes, services, daemons, or the like, for example those illustrated in FIGS. 1 and 5 other than the FPGA 10.

The processor 18 may also include hardware components such as registers, finite-state machines, sequential and combinational logic, configurable logic blocks, and other electronic circuits that can perform the functions necessary for the operation of various examples of the present technology. In various examples, the processor 18 may include multiple computational components and functional blocks that are packaged separately but function as a single unit. In various examples, the processor 18 may further include multiprocessor architectures, parallel processor architectures, processor clusters, and the like, which provide high performance computing. The processor 18 may be in electronic communication with the other electronic components of the computing device 12 through serial or parallel links that include universal busses, address busses, data busses, control lines, and the like. In addition, the processor 18 may include analog to digital converters (ADCs) to convert analog electronic signals to digital data values in binary form (such as by sampling), or streams of digital data values, and/or digital to analog converters (DACs) to convert digital data values, or streams of digital data values, to analog electronic signals.

Returning to FIG. 1, the user drafts a source code 20 that describes the design at a high level and includes a plurality of statements describing the functional aspects, one or more flows of data, or both without granular specification of physical components or subset(s) of physical component(s). That is, the source code 20 usually describes what the design does—not what the design is. And, the source code 20 does not call out any specific CLBs or interconnect structures although it is possible that one or more higher function blocks and memory and I/O blocks may be explicitly named. The source code 20 may be written in various high-level computer programming languages including register-transfer language (RTL), although examples of the source code 20 discussed herein are written in C++. As used herein, “specific” or “granular”—when used in contrast with “high-level” or the like-refers to unique identification of a component or signal, whether by unique identification by name or other identifier, or by specifying a place and time (or time range) at which the identified signal is to be sampled, measured, captured or observed. In turn, “high-level” means a more abstract or less specific description, such as where a component or signal type, characteristic or function is given without unique identification.

When the source code 20 is complete, the user starts the process of programming (putting the design into) the FPGA 10. The functional blocks, except for the FPGA 10, shown in FIG. 1—which program the FPGA 10 and analyze data output by the FPGA 10—may be embodied by a plurality of software modules, programs or algorithms which receive data, process at least a portion of the data, and output at least a portion of the processed data or data generated based on the received or processed data. The software modules may be executed or implemented by one or more computing devices 12.

The source code 20 is received by a high level synthesis (HLS) tool 22, which converts the C++ source code 20 into a design hardware description language (HDL) code, such as Verilog or very high-speed integrated circuit hardware description language (VHDL) code, and outputs the HDL code. The design HDL code may include RTL statements or commands that are used for synthesizing circuitry in the FPGA 10. The design HDL code may further include specific instances of components formed from CLBs, higher function blocks, and memory and I/O blocks.

The HLS tool 22 also follows a set of rules, implements algorithmic processes, or both to analyze the HDL code and output a high-level instrumentation specification 24 which includes one or more statements that indicate a level of ports, a level of signals, and a level of operating parameters for memory components and input/output (I/O) components in the FPGA 10 to instrument. The ports are input/output ports of the components formed by the CLBs, the higher function blocks, or both. The signals are signals that pass data from one component to another or signals that stay within a component. The memory components may include first-in, first-out (FIFO) registers, among others. The I/O components may include video interfaces, network interfaces, external memory interfaces, and the like. In addition, data-related metrics, such as network packets per second and video frames per second for I/O components, data throughput rates for memory components, such as bytes per second, clock rates, and the like may instrumented or monitored.

The rules, algorithmic processes, or both utilized by the HLS tool 22 may map predefined statements in the HDL code regarding entities, signals, data flow, and block instances into javascript object notation (.json) code in the high-level instrumentation specification 24 that lists the components or objects to be instrumented along with a plurality of specifications discussed below. The high-level instrumentation specification 24 may also include key-value specification statements such as yet another markup language (yaml) or initialization (.ini) code.

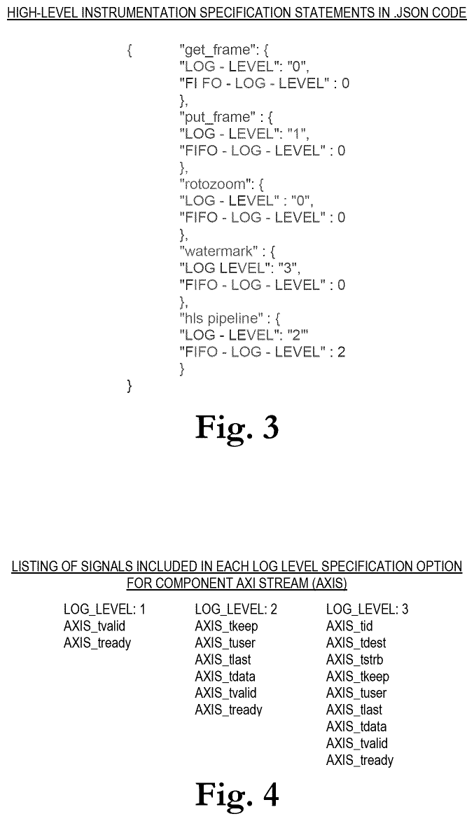

Referring to FIG. 3, the high-level instrumentation specification 24 statements may be implemented as one or more functions and may include a “LOG_LEVEL” specification as well as a “FIFO_LOG_LEVEL” specification. The exemplary statements include “LOG_LEVEL” and “FIFO_LOG_LEVEL” specifications for each of five components or objects, including “get_frame”, “put_frame”, “rotozoom”, “watermark”, and “hls_pipeline”. The “LOG_LEVEL” specification is set to one of a plurality of values for corresponding ones of the components or objects, wherein each value indicates a level of ports and signals, the specific ports and signals, or both, that will be monitored or observed. The different values provide different levels of monitoring, with a large value providing monitoring of a large number of ports and signals and a small value providing monitoring of a small number of ports and signals.

Referring to FIG. 4, an example of a listing of signals is presented for each one of three values (“1”, “2”, and “3”) of “LOG_LEVEL” for a component or object named “axi stream”, wherein a value of “1” for the “LOG_LEVEL” includes two signals, a value of “2” for the “LOG_LEVEL” includes six signals, and a value of “3” for the “LOG_LEVEL” includes nine signals. In various examples, a value of “1” for the “LOG_LEVEL” may indicate that just handshake signals are instrumented, a value of “2” for the “LOG_LEVEL” may indicate that handshake signals and some data signals are instrumented, and a value of “3” for the “LOG_LEVEL” may indicate that all ports and signals are instrumented. A value of “0” for the “LOG_LEVEL” indicates that no signals will be instrumented or monitored.

The “FIFO_LOG_LEVEL” specification is set to one of a plurality of values for corresponding ones of the components or objects, wherein each value indicates a level of monitoring or observability of the operating parameters or performance of selected memory components, with a large value providing monitoring of a large number of operating parameters and a small value providing monitoring of a small number of operating parameters. The values of “FIFO_LOG_LEVEL” may include “0”, “1”, and “3”, for example, wherein the signals that may be instrumented include “full”, “empty”, “occupancy”, “write_data”, “read_data”, “write_en”, and “read_en”, with none of the signals being instrumented for a value of “0”, at least a portion of the signals being instrumented for a value of “1”, and all of the signals being instrumented for a value of “3”.

Additional instrumentation options include options to configure the dashboard, such as max_iterations, show_markers, monitoring_mode, and waveform_period, and options to configure the generated probing circuitry, including sample buffer depth and an identification name among others.

The user may edit the high-level instrumentation specification 24 to selectively modify the “LOG_LEVEL” specification and the “FIFO_LOG_LEVEL” specification values. The user may also edit the high-level instrumentation specification 24 to selectively add data-related metrics.

The high-level instrumentation specification 24 is received by a high-level instrumentor 26 which converts the high-level instrumentation specification 24 into and outputs a low-level instrumentation specification. The low-level instrumentation specification is written in tool command language (TCL) code or other scripting language, such as Python, and includes statements identifying the specific ports and signals that will be monitored or observed. The low-level instrumentation specification also includes statements identifying specific operating parameters for specific memory and I/O components in the FPGA 10 to monitor. The high-level instrumentor 26 may follow a set of rules, implement algorithmic processes, or both to generate a listing of the specific signals, ports, and the like in the low-level instrumentation specification according to the code in the high-level instrumentation specification 24. For example, with reference to FIG. 4, the high-level instrumentor 26 may generate the signals listed in one of the columns for the exemplary component axi stream according to the value of the “LOG_LEVEL”, which is specified in the high-level instrumentation specification 24. In addition, the high-level instrumentor 26 may parse the high-level instrumentation specification 24 for user-added components and data-related metrics.

The low-level instrumentation specification is received by a low-level instrumentor 28 which converts the low-level instrumentation specification into and outputs an instrumentation HDL code that includes constraints and a listing of the specific ports and signals and memory and I/O component operating parameters to be monitored. The low-level instrumentor 28 may follow a set of rules, implement algorithmic processes, or both to map the specifications regarding signals, ports, and the like from the low-level instrumentation specification to HDL code statements targeted to the FPGA 10.

The design HDL code from the HLS tool 22 and the instrumentation HDL code from the low-level instrumentor 28 are received by an FPGA programmer 30 which performs logic circuit synthesis, among other functions, and converts the code into a circuit netlist or configuration for the FPGA 10, for example to program the FPGA 10. The netlist includes the circuitry necessary for the original design according to the design HDL code as well as additional circuitry to provide instrumenting or monitoring of ports, signals, and memory and I/O components according to the instrumentation HDL code. The netlist is programmed or loaded into the FPGA 10, for example in a serial or bitstream fashion. The FPGA programmer 30 also feeds back information about the synthesized circuitry to the high-level instrumentor 26, which incorporates the information about ports, signals, and memory and I/O components as well as a hierarchy of the instantiated components within the overall design into the low-level instrumentation specification that is output to the low-level instrumentor 28. The design is searched in order to determine the hierarchy of the design so that the user does not have to input any hierarchy information.

A triggering unit 32 receives the high-level instrumentation specification 24 from the HLS tool 22 and generates triggering data written in TCL code which sets up triggering for each of the ports, signals, and memory and I/O component parameters indicated in the high-level instrumentation specification 24. The triggering includes a determination or retrieval, such as by sampling, of a data value for each of the ports, signals, and memory and I/O component parameters at one or more time periods or when certain events or conditions occur. For example, all of the ports, signals, and memory and I/O component parameters may be sampled once per time period, which may range from milliseconds to seconds. Or, a first grouping of ports, signals, and memory and I/O component parameters may be sampled at a first data rate, while a second grouping of ports, signals, and memory and I/O component parameters may be sampled at a second data rate, and so forth. In addition, some data may be sampled when certain events or conditions occur, such as when data reaches a certain value, or the like. The triggering unit 32 may follow a set of rules, implement algorithmic processes, or both to map the data from the high-level instrumentation specification 24 to triggering data that can be used to view waveforms.

A debugger 34 receives the triggering data from the triggering unit 32 as well as optional manual triggering commands from the user. Furthermore, the debugger 34 interfaces with the FPGA 10 to receive data from the FPGA 10 regarding, or actually from, the ports, signals, and memory and I/O component parameters that were programmed to be instrumented or monitored. The data received from the FPGA 10 may be determined by, or vary according to, the triggering data from the triggering unit 32. The debugger 34 outputs a dumpfile written in value change dump (.vcd) code that includes data derived from the triggering data and the data received from the FPGA 10. The debugger 34 may also output the dumpfile in a custom coded binary data format.

A waveform viewer updater 36 receives the dumpfile and outputs a waveform update file derived from the dumpfile including the data received from the FPGA 10 in a format that is ready for display in one or more types of waveform viewer, dashboard, or both. The waveform viewer updater 36 may follow a set of rules, implement algorithmic processes, or both to map the data from the dumpfile to data formatted to view waveforms. Some waveform viewers, dashboards, or both operate with TCL code, while others may operate with Python code, while still others may operate with fast signal database (.fsdb) code wave log format (.wlf) code, or value change dump (.vcd) code. The waveform viewer updater 36 outputs the waveform update file in one or more of a plurality of languages or formats according to the waveform viewer, dashboard, or other software program which will display the data, waveforms, or both.

An initial waveform viewer configuration tool 38 receives the low-level instrumentation specification from the high-level instrumentor 26 and outputs a waveform setup file derived from the low-level instrumentation specification to set up a waveform viewer, a dashboard, or both to display data from the ports, signals, and memory and I/O component parameters specified in the low-level instrumentation specification. The initial waveform viewer configuration tool 38 may follow a set of rules, implement algorithmic processes, or both to map the data from the low-level instrumentation specification to data formatted to set up a waveform viewer.

A waveform viewer and dashboard 40 receives the waveform setup file from the initial waveform viewer configuration tool 38 and the waveform update file from the waveform viewer updater 36. The waveform viewer displays data from the ports and signals as waveforms over time, such as displaying one waveform for each port and each signal. The dashboard displays data from each of the memory components, such as fill level, or from the ports and signals in the form of charts, graphs, and the like. The dashboard may also display I/O component data-related metrics, such as network packets per second, video frames per second, data throughput rates for memory components, such as bytes per second, clock rates, and the like. The waveform viewer and dashboard 40 may include viewers or dashboard components or plug-ins from nearly any vendor.

Referring to FIG. 5, a diagram illustrating a flow of a method for providing on-chip instrumentation for use with the FPGA 10 is shown. The method includes substantially the same steps as described above in connection with the method of FIG. 1, except that the user may specify the levels of ports, the levels of signals, and the levels of operating parameters for memory components in the FPGA 10 to instrument directly in the source code 20. The HLS tool 22 receives the source code and outputs the high-level instrumentation specification for the high-level instrumentor 26 and the triggering unit 32 without the need for substantial or any intermediate editing or updating. The rest of the flow of the second method continues as described above for the first method.

Throughout this specification, references to “one example”, “an example”, or “examples” mean that the feature or features being referred to are included in at least one example of the technology. Separate references to “one example”, “an example”, or “examples” in this description do not necessarily refer to the same example and are also not mutually exclusive unless so stated and/or except as will be readily apparent to those skilled in the art from the description. For example, a feature, structure, act, etc. described in one example may also be included in other examples, but is not necessarily included. Thus, the current technology can include a variety of combinations and/or integrations of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain examples are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In examples, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various examples, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering examples in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In examples in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some examples, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some examples, the processors may be located in a single location (e.g., within a home environment, an office environment or as a server farm), while in other examples the processors may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112 (f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A method for providing on-chip instrumentation for a field programmable gate array (FPGA), the method comprising:
receiving a source code which specifies a design to be programmed into the FPGA and includes a plurality of statements describing a function of the design, one or more flows of data, or both;
generating a high-level instrumentation specification derived from the source code and which includes one or more statements that indicate a level of ports, a level of signals, and a level of operating parameters for memory and input/output components in the FPGA to instrument;
generating a low-level instrumentation specification derived from the high-level instrumentation specification and which includes one or more statements that identify a plurality of specific ports, a plurality of specific signals, and a plurality of specific operating parameters for specific and input/output memory components in the FPGA to instrument;
receiving a dumpfile that includes data regarding the specific ports, the specific signals, and the specific operating parameters derived from data received from the FPGA;
generating a waveform update file derived from the dumpfile that includes data from the FPGA regarding the specific ports, the specific signals, and the specific operating parameters, the data generated in a format for viewing in a waveform viewer; and
generating triggering data to determine a plurality of times at which the specific signals are sampled.

2. The method of claim 1, comprising:
generating a design hardware description language (HDL) code that describes the design;
generating an instrumentation HDL code that describes circuitry to provide instrumenting of the specific ports, the specific signals, and the operating parameters of the specific memory and input/output components; and
programming the FPGA, in part using the design HDL code and the instrumentation HDL code, to include the design and additional circuitry that outputs data regarding the specific ports, the specific signals, and the operating parameters of the specific memory and input/output components.

3. The method of claim 1, comprising receiving edits from a user to the high-level instrumentation specification to modify at least one of the level of ports, the level of signals, and the level of operating parameters.

4. The method of claim 1, comprising displaying a plurality of waveforms with one waveform being displayed for each port and each signal.

5. The method of claim 1, comprising displaying a dashboard which indicates a fill level for each of the memory components.

6. The method of claim 1, comprising
receiving the triggering data and data from the FPGA regarding the ports, the signals, and the memory and input/output component operating parameters to be instrumented, and
generating the dumpfile to include data derived from the triggering data and data from the FPGA.

7. The method of claim 6, comprising receiving manual triggering commands from a user.

8. The method of claim 1, comprising generating a waveform setup file derived from the low-level instrumentation specification, the waveform setup file to set up a waveform viewer, a dashboard, or both to display data from the ports, signals, and memory and input/output component parameters specified in the low-level instrumentation specification.

9. The method of claim 1, wherein the level of signals of the high-level instrumentation specification includes a first level that indicates a first number of signals to be instrumented, a second level that indicates a second number of signals to be instrumented, and a third level that indicates a third number of signals to be instrumented.

10. The method of claim 9, wherein the second number is greater than the first number and the third number is greater than the second number.

11. The method of claim 1, wherein the source code is written in C++ or a register transfer language.

12. The method of claim 1, wherein the high-level instrumentation specification is written in javascript object notation (json) code or includes key-value specifications.

13. The method of claim 1, wherein the low-level instrumentation specification is written in a scripting language.

14. The method of claim 1, wherein the dumpfile is written in a code according to a waveform viewer or dashboard that receives the dumpfile.

15. The method of claim 1, wherein the triggering data is written in tool command language (tcl) code or python.

16. A method for providing on-chip instrumentation for a field programmable gate array (FPGA), the method comprising:
receiving a source code from a user which specifies a design to be programmed into the FPGA and includes a plurality of statements describing a function of the design, one or more flows of data, or both, and one or more statements that indicate a level of ports, a level of signals, and a level of operating parameters for memory and input/output components in the FPGA to instrument;
generating a low-level instrumentation specification derived from the source code and which includes one or more statements that identify a plurality of specific ports, a plurality of specific signals, and a plurality of specific operating parameters for specific memory and input/output components in the FPGA to instrument;
receiving a dumpfile that includes data regarding the specific ports, the specific signals, and the specific operating parameters derived from data received from the FPGA;
generating a waveform update file derived from the dumpfile that includes data from the FPGA regarding the specific ports, the specific signals, and the specific operating parameters, the data generated in a format for viewing in a waveform viewer; and
generating triggering data to determine a plurality of times at which the specific signals are sampled.

17. A plurality of software modules operating in combination for providing on-chip instrumentation for a field programmable gate array (FPGA), the software modules comprising:
a high-level synthesis tool to
receive a source code which specifies a design to be programmed into the FPGA and includes a plurality of statements describing a function of the design, one or more flows of data, or both,
generate a high-level instrumentation specification derived from the source code and which includes one or more statements that indicate a level of ports, a level of signals, and a level of operating parameters for memory and input/output components in the FPGA to instrument, and
generate a design hardware description language (HDL) code that describes the design;
a high-level instrumentor to receive the high-level instrumentation specification and generate a low-level instrumentation specification derived from the high-level instrumentation specification and which includes one or more statements that identify a plurality of specific ports, a plurality of specific signals, and a plurality of specific operating parameters for specific memory and input/output components in the FPGA to instrument;
a triggering unit to receive the high-level instrumentation specification and generate triggering data to determine a plurality of times at which the specific signals are sampled; and
a waveform viewer updater to
receive a dumpfile that includes data regarding the specific ports, the specific signals, and the specific operating parameters derived from data received from the FPGA, and
generate a waveform update file derived from the dumpfile that includes data from the FPGA regarding the specific ports, the specific signals, and the specific operating parameters, the data generated in a format for viewing in a waveform viewer.

18. The software modules of claim 17, comprising an initial waveform viewer configuration tool to receive the low-level instrumentation specification and generate a waveform setup file to set up a waveform viewer, a dashboard, or both to display data from the ports, signals, and memory and input/output component parameters specified in the low-level instrumentation specification.

19. The software modules of claim 17, comprising
a low-level instrumentor to generate an instrumentation HDL code that describes circuitry to provide instrumenting of the specific ports, the specific signals, and the operating parameters of the specific memory and input/output components; and
an FPGA programmer to program the FPGA, in part using the design HDL code and the instrumentation HDL code, to include the design and additional circuitry that outputs data regarding the specific ports, the specific signals, and the operating parameters of the specific memory and input/output components.

20. The software modules of claim 17, comprising a debugger to
receive the triggering data and data from the FPGA regarding the ports, the signals, and the memory and input/output component operating parameters to be instrumented, and
generate the dumpfile to include data derived from the triggering data and data from the FPGA.
